(19) United States
(12) Patent Application Publication
(10) Pub. No.: US 2024/0213123 A1
(43) Pub. Date: Jun. 27, 2024

(54) SEMICONDUCTOR DEVICE

(71) Applicant: DENSO CORPORATION, Kariya-city (JP)

(72) Inventor: SACHIO KODAMA, Kariya-city (JP)

(21) Appl. No.: 18/468,773

(22) Filed: Sep. 18, 2023

(30) Foreign Application Priority Data
Dec. 21, 2022 (JP) 2022-204759

(51) Int. Cl. H01L 23/495; H01L 23/00; H01L 23/31

(52) U.S. Cl. CPC H01L 23/49541; H01L 23/3107; H01L 23/49517; H01L 23/49537; H01L 24/32; H01L 24/33; H01L 24/48; H01L 24/73; H01L 2224/32245; H01L 2224/33181; H01L 2224/48175; H01L 2224/73215; H01L 2224/73265

(57) ABSTRACT

A semiconductor device includes: a semiconductor element having a first main electrode and a second main electrode; a first wiring member electrically connected to the first main electrode; a second wiring member electrically connected to the second main electrode; and a conductive spacer interposed between the semiconductor element and the first wiring member. The conductive spacer has an end surface facing the semiconductor element and a side surface continuous with the end surface. The side surface has a recess open in the end surface and located adjacent to a pad in a plan view. The side surface has a roughened region in which a roughened oxide film is formed excluding an inner surface of the recess, and a non-roughened region, in which the roughened oxide film is not formed, on the inner surface of the recess.

### CROSS REFERENCE TO RELATED APPLICATION

This application is based on Japanese Patent Application No. 2022-204759 filed on Dec. 21, 2022, the disclosure of which is incorporated herein by reference.

### TECHNICAL FIELD

The present disclosure relates to a semiconductor device.

### BACKGROUND

A semiconductor device has a double-sided heat dissipation structure.

### SUMMARY

A semiconductor device includes: a semiconductor element having a first main electrode and a second main electrode; a first wiring member electrically connected to the first main electrode; a second wiring member electrically connected to the second main electrode; a conductive spacer interposed between the semiconductor element and the first wiring member; and a solder disposed between the second wiring member and the second main electrode, between the first main electrode and the conductive spacer, and between the conductive spacer and the first wiring member. The conductive spacer has an end surface facing the semiconductor element and a side surface continuous with the end surface. The side surface has a recess open in the end surface and located adjacent to a pad in a plan view along the thickness direction. The side surface has a roughened region in which a roughened oxide film is formed, excluding an inner surface of the recess. The inner surface of the recess has a non-roughened region in which the roughened oxide film is not formed.

### BRIEF DESCRIPTION OF THE DRAWINGS

FIG. 1 is a schematic diagram illustrating a configuration of a vehicle drive system to which a semiconductor device according to a first embodiment is applied.

FIG. 2 is a plan view illustrating the semiconductor device of the first embodiment.

FIG. 3 is a cross-sectional view taken along a line III-III of FIG. 2.

FIG. 4 is a cross-sectional view taken along a line IV-IV of FIG. 2.

FIG. 5 is a plan view illustrating a semiconductor element.

FIG. 6 is a cross-sectional view taken along a line VI-VI of FIG. 5.

FIG. 7 is a cross-sectional view taken along a line VII-VII of FIG. 4.

FIG. 8 is a side view of the semiconductor device viewed in an arrow direction Y1 of FIG. 7.

FIG. 9 is a cross-sectional view taken along a line IX-IX of FIG. 8.

FIG. 10 is a diagram illustrating a modification.

FIG. 11 is a diagram illustrating a modification.

FIG. 12 is a diagram illustrating a modification.

FIG. 13 is a diagram illustrating a modification.

FIG. 14 is a plan view illustrating a semiconductor element of a semiconductor device according to a second embodiment.

FIG. 15 is a cross-sectional view taken along a line XV-XV of FIG. 14.

FIG. 16 is a partial sectional view illustrating a connection structure between a semiconductor element and a conductive spacer.

FIG. 17 is a diagram illustrating a modification.

FIG. 18 is a diagram illustrating a modification.

FIG. 19 is a side view of the conductive spacer viewed in an arrow direction Y2 of FIG. 18.

FIG. 20 is a diagram illustrating a modification.

FIG. 21 is a diagram illustrating a modification.

FIG. 22 is a diagram illustrating a modification.

### DETAILED DESCRIPTION

A semiconductor device has a double-sided heat dissipation structure. The disclosure of US 2017/0278774 A1 (JP 2016-197706 A) is incorporated herein by reference to explain technical elements described herein.

A conductive spacer is interposed between a main electrode of a semiconductor element and a wiring member. A concavo-convex oxide film having a continuously concavo-convex surface is formed on the side surface of the conductive spacer by laser irradiation. Adhesion to the sealing body can be enhanced by a roughened portion formed of the concavo-convex oxide film. However, the concavo-convex oxide film has low wettability to solder. If the solder overflows from the main electrode toward the pad, a short circuit of the pad may occur. For example, a short circuit between the pad and the main electrode or a short circuit between the pads may occur. From the above viewpoint or from other viewpoints not mentioned, further improvement is required for the semiconductor device.

The present disclosure provides a semiconductor device capable of suppressing a short circuit of a pad.

A semiconductor device includes: a semiconductor element having a first main electrode and a second main electrode; a first wiring member electrically connected to the first main electrode; a second wiring member electrically connected to the second main electrode; a conductive spacer interposed between the semiconductor element and the first wiring member; and a solder disposed between the second wiring member and the second main electrode, between the first main electrode and the conductive spacer, and between the conductive spacer and the first wiring member. The conductive spacer has an end surface facing the semiconductor element and a side surface continuous with the end surface. The side surface has a recess open in the end surface and located adjacent to a pad in a plan view along the thickness direction. The side surface has a roughened region in which a roughened oxide film is formed, excluding an inner surface of the recess. The inner surface of the recess has a non-roughened region in which the roughened oxide film is not formed.

Accordingly, if the solder overflows from the main electrode to the pad, the solder wets and spreads to the non-roughened region provided on the side surface of the conductive spacer and is received in the recess. Accordingly, it is possible to suppress the overflowing solder from reaching the pad. As a result, it is possible to provide a semiconductor device capable of suppressing a short circuit of a pad.

A semiconductor device includes: a semiconductor element having a semiconductor substrate, a first main electrode and a signal pad provided on one surface of the semiconductor substrate, and a second main electrode provided on a back surface opposite to the one surface in a thickness direction; a first wiring member electrically connected to the first main electrode; a second wiring member electrically connected to the second main electrode, the semiconductor element being received between the first wiring member and the second wiring member in the thickness direction; a conductive spacer interposed between the semiconductor element and the first wiring member; and a solder disposed between the second wiring member and the second main electrode, between the first main electrode and the conductive spacer, and between the conductive spacer and the first wiring member. A bonding portion of the first main electrode bonded with the conductive spacer and the pad are arranged in a first direction orthogonal to the thickness direction. The semiconductor element includes a dummy wiring extending from an end of the bonding portion of the first main electrode adjacent to the pad and arranged in parallel with the pad in a second direction orthogonal to the thickness direction and the first direction.

Accordingly, if the solder overflows from the bonding portion of the main electrode to the pad, the solder wets and spreads to the dummy wiring of the semiconductor element and is held on the dummy wiring. Accordingly, it is possible to suppress the overflowing solder from reaching the pad. As a result, it is possible to provide a semiconductor device capable of suppressing a short circuit of a pad.

The disclosed aspects in this specification adopt different technical solutions from each other in order to achieve their respective objectives. The objectives, features, and effects disclosed herein are further clarified by reference to the subsequent detailed description and accompanying drawings.

Hereinafter, multiple embodiments will be described with reference to the drawings. The same or corresponding elements in the embodiments are assigned the same reference numerals, and descriptions thereof will not be repeated. When only a part of the configuration is described in one embodiment, the other parts of the configuration may employ descriptions about a corresponding configuration in another embodiment preceding the one embodiment. Further, not only the combinations of the configurations explicitly shown in the description of the respective embodiments, but also the configurations of multiple embodiments can be partially combined even when they are not explicitly shown while there is no difficulty in the combination in particular.

The semiconductor device according to the present embodiment is applicable to, for example, a power conversion device for a moving object with a rotary electric machine as a drive source. The moving object is, for example, an electric vehicle such as a BEV, an HEV, or a PHEV, a flying object such as an electric vertical take-off and landing aircraft or a drone, a ship, a construction machine, or an agricultural machine. BEV is an abbreviation for Battery Electric Vehicle. HEV is an abbreviation for Hybrid Electric Vehicle. PHEV is an abbreviation for Plug-in Hybrid Electric Vehicle. Hereinafter, as an example, the semiconductor device is applied to a vehicle.

### First Embodiment

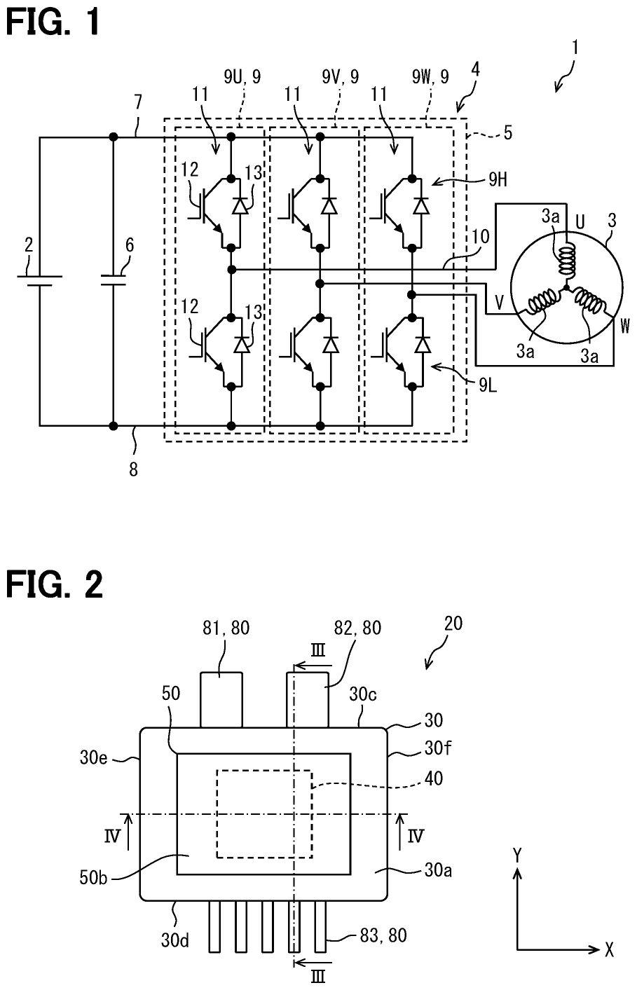

The following describes a schematic configuration of a vehicle drive system with reference to FIG. 1.

### Vehicle Drive System

As shown in FIG. 1, a vehicle drive system 1 is provided with a DC power supply 2, a motor generator 3, and a power conversion device 4.

The DC power supply 2 is a direct-current voltage source including a chargeable/dischargeable secondary battery. The secondary battery is, for example, a lithium ion battery or a nickel hydride battery. The motor generator 3 is a three-phase AC type rotating electric machine. The motor generator 3 functions as a vehicle driving power source, that is, an electric motor. The motor generator 3 functions also as a generator during regeneration. The power conversion device 4 performs electric power conversion between the DC power supply 2 and the motor generator 3.

### Power Conversion Device

FIG. 1 shows a circuit configuration of the power conversion device 4. The power conversion device 4 includes at least a power conversion circuit such as an inverter 5. The power conversion device 4 includes a smoothing capacitor 6 in addition to the inverter 5.

The smoothing capacitor 6 mainly smooths the DC voltage supplied from the DC power supply 2. The smoothing capacitor 6 is connected to a P line 7 which is a power supply line on the high potential side and an N line 8 which is a power supply line on the low potential side. The P line 7 is connected to a positive electrode of the DC power supply 2, and the N line 8 is connected to a negative electrode of the DC power supply 2. The positive electrode of the smoothing capacitor 6 is connected to the P line 7 between the DC power supply 2 and the inverter 5. The negative electrode of the smoothing capacitor 6 is connected to the N line 8 at a position between the DC power supply 2 and the inverter 5. The smoothing capacitor 6 is connected in parallel with the DC power supply 2.

The inverter 5 is a DC-AC conversion circuit. The inverter 5 converts a DC voltage into a three-phase AC voltage, and outputs the AC voltage to the motor generator 3 according to switching control by a control circuit (not illustrated). Thereby, the motor generator 3 is driven to generate a predetermined torque. At the time of regenerative braking of the vehicle, the inverter 5 converts the three-phase AC voltage generated by the motor generator 3 by receiving the rotational force from the wheels into a DC voltage according to the switching control by the control circuit, and outputs the DC voltage to the P line 7. In this way, the inverter 5 performs bidirectional power conversion between the DC power supply 2 and the motor generator 3.

The inverter 5 includes upper and lower arm circuits 9 for each of the three phases. The upper and lower arm circuits 9 are also referred to as legs. Each of the upper and lower arm circuits 9 has an upper arm 9H and a lower arm 9L. The upper arm 9H and the lower arm 9L are connected in series between the P line 7 and the N line 8, and the upper arm 9H is located adjacent to the P line 7.

The connection point between the upper arm 9H and the lower arm 9L, that is, the midpoint of the upper and lower arm circuits 9 is connected to the winding 3a of the corresponding phase in the motor generator 3 via the output line 10. Among the upper and lower arm circuits 9, the upper and lower arm circuits 9U of the U phase are connected to the winding 3a of the U phase via the output line 10. The upper and lower arm circuits 9V of the V phase are connected to the winding 3a of the V phase via the output line 10. The upper and lower arm circuits 9W of the W phase are connected to the winding 3a of the W phase via the output line 10.

The upper and lower arm circuits 9 (9U, 9V, 9W) includes a series circuit 11. The upper and lower arm circuits 9 may include one series circuit 11 or plural series circuits. In case where the upper and lower arm circuits 9 have plural series circuits, the series circuits 11 are connected in parallel to each other to form the upper and lower arm circuits 9 for one phase. In the present embodiment, each of the upper and lower arm circuits 9 includes one series circuit 11. The series circuit 11 is configured by connecting a switching element of the upper arm 9H and a switching element of the lower arm 9L in series between the P line 7 and the N line 8.

The number of high-side switching elements and the number of low-side switching elements included in the series circuit 11 are not particularly limited. The number thereof may be one or more. The series circuit 11 of the present embodiment includes one switching element on the high side and one switching element on the low side.

In the present embodiment, as the switching element, n-channel type IGBT 12 is employed. IGBT is an abbreviation for Insulated Gate Bipolar Transistor. A freewheeling diode 13 is connected in antiparallel to each of the IGBTs 12. Hereinafter, the diode 13 may be referred to as an FWD13. In the upper arm 9H, the collector of the IGBT12 is connected to the P line 7. In the lower arm 9L, the emitter of the IGBT12 is connected to the N line 8. The emitter of the IGBT 12 in the upper arm 9H and the collector of the IGBT 12 in the lower arm 9L are connected to each other. The anode of the diode 13 is connected to the emitter of the corresponding IGBT 12, and the cathode is connected to the collector.

The switching element is not limited to the IGBT 12. For example, a MOSFET may be employed. MOSFET stands for Metal-Oxide-Semiconductor Field-Effect Transistor. In the case of a MOSFET, the FWD may be a parasitic diode (body diode) or an external diode.

The power conversion device 4 may further include a converter as a power conversion circuit. The converter is a DC-DC converter circuit for converting the DC voltage to a DC voltage with different value. The converter is provided between the DC power supply 2 and the smoothing capacitor 6. The converter may include, for example, a reactor and the above-described upper and lower arm circuits 9. This configuration can boost/suppress voltage. The power conversion device 4 may further include a filter capacitor for removing power supply noise from the DC power supply 2. The filter capacitor is provided between the DC power supply 2 and the converter.

The power conversion device 4 may include a drive circuit for a switching element of the inverter 5. The drive circuit supplies a drive voltage to the gate of the IGBT 12 of the corresponding arm based on the drive command of the control circuit. The drive circuit drives, i.e., turns on and turns off, the corresponding IGBT 12 by applying a drive voltage. The drive circuit may be referred to as a “driver”.

The power conversion device 4 may include a control circuit for the switching element. The control circuit generates a drive command for operating the IGBT 12 and outputs the drive command to the drive circuit. The control circuit generates the drive command based on a torque request input from a higher-level ECU (not shown) or signals detected by various sensors. Examples of the various sensors include a current sensor, a rotation angle sensor, and a voltage sensor. The current sensor detects the phase current flowing through the winding 3a of each phase. The rotation angle sensor detects a rotation angle of a rotor of the motor generator 3. The voltage sensor detects a voltage the across smoothing capacitor 6. The control circuit outputs, for example, a PWM signal as the drive command. The control circuit includes, for example, a processor and a memory. ECU is an abbreviation of Electronic Control Unit. PWM is an abbreviation for Pulse Width Modulation.

### Semiconductor Device

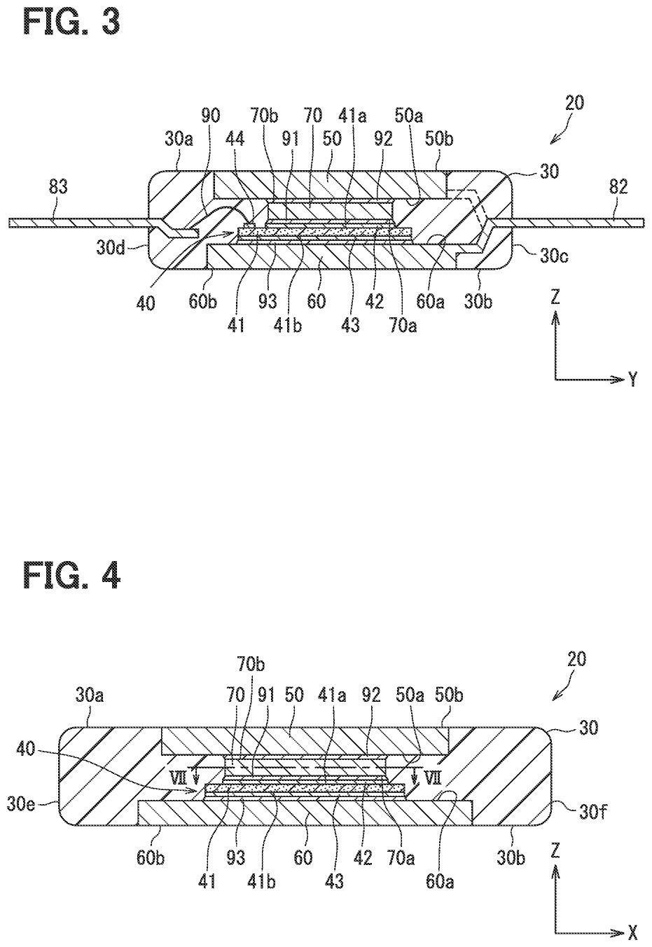

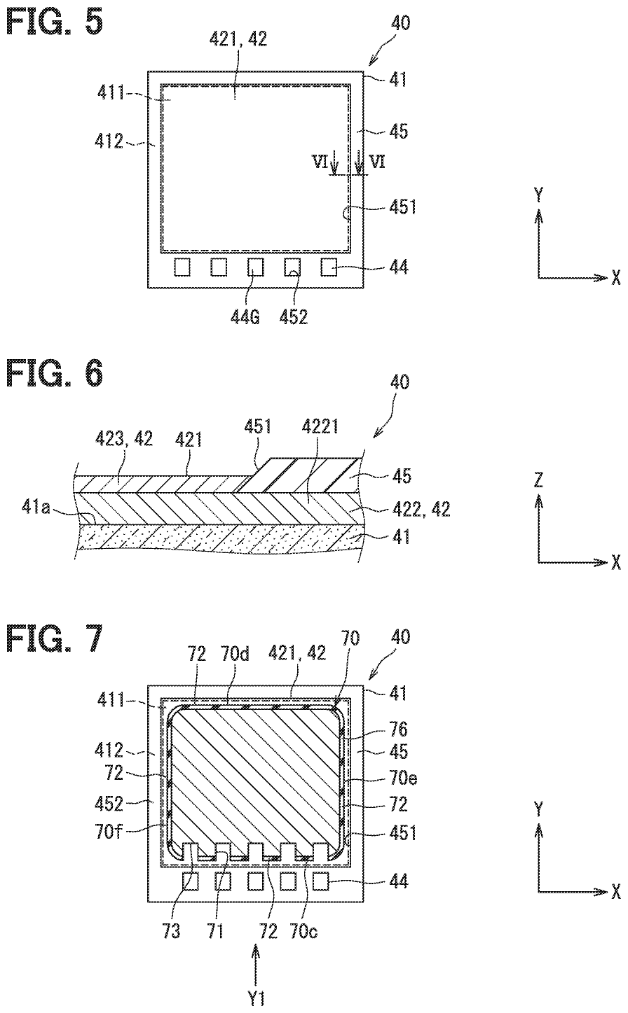

A schematic structure of a semiconductor device will be described based on FIGS. 2 to 6. FIG. 2 is a plan view illustrating the semiconductor device. FIG. 2 is a plan view of the semiconductor device from the upper side. FIG. 3 is a cross-sectional view taken along a line III-III of FIG. 2. FIG. 4 is a cross-sectional view taken along a line IV-IV of FIG. 2. FIG. 5 is a plan view showing the semiconductor element. FIG. 6 is a cross-sectional view taken along a line VI-VI of FIG. 5. In FIGS. 3 and 4, a concave-convex oxide film (roughened region) to be described later is omitted from the conductive spacer for the sake of convenience.

Hereinafter, a thickness direction of the semiconductor element, in other words, a semiconductor substrate is defined as a Z direction. One direction orthogonal to the Z direction is defined as an X direction. A direction orthogonal to both the Z direction and the X direction is defined as a Y direction. The X direction, the Y direction, and the Z direction are arranged to be orthogonal to each other. Unless otherwise specified, a shape viewed in a plane from the Z-direction, that is, a shape along an XY plane defined by the X-direction and Y-direction is referred to as a planar shape. A plan view from the Z direction may be simply referred to as a plan view.

As shown in FIGS. 2 to 6, the semiconductor device 20 includes a sealing body 30, a semiconductor element 40, a wiring member 50, 60, a conductive spacer 70, and an external connection terminal 80. The semiconductor device 20 further includes a bonding wire 90 and a solder 91, 92, 93. As an example, the semiconductor device 20 of the present embodiment constitutes one of the arms described above. That is, the upper and lower arm circuits 9 for one phase are configured by the two semiconductor devices 20.

The sealing body 30 seals parts of the semiconductor device 20. The rest of the components are exposed to the outside of the sealing body 30. The sealing body 30 is made of, for example, resin. An example of the resin is epoxy resin. The sealing body 30 is molded by, for example, a transfer molding method using resin as a material. Such a sealing body 30 may be referred to as a sealing resin body, a molded resin, a resin molded body, or the like. The sealing body 30 may be formed using, for example, gel. The gel is filled (disposed), for example, in opposing regions of the wiring member 50 and the wiring member 60.

As shown in FIG. 2, the sealing body 30 has a substantially rectangular shape in plan view. The sealing body 30 has one surface 30a and a back surface 30b opposite to the one surface 30a in the Z direction, as the outer surface. The one surface 30a and the back surface 30b are, for example, substantially flat surfaces. Side surfaces 30c, 30d, 30e, and 30f are defined to connect the one surface 30a and the back surface 30b. The main terminals 81 and 82 of the external connection terminal 80 protrude from the side surface 30c. The side surface 30d is opposite to the side surface 30c in the Y direction. The signal terminal 83 protrudes from the side surface 30d. The external connection terminal 80 does not protrude from the side surface 30e, 30f. The side surface 30e is opposite to the side surface 30f in the X direction.

The semiconductor element 40 includes a semiconductor substrate 41, an emitter electrode 42, a collector electrode 43, and a pad 44. The semiconductor element 40 is sometimes referred to as a semiconductor chip. The semiconductor substrate 41 is formed of a material such as silicon (Si) or a wide bandgap semiconductor having a bandgap wider than that of silicon, and a vertical element is formed. Examples of the wide bandgap semiconductor include silicon carbide (SiC), gallium nitride (GaN), gallium oxide (Ga₂O₃), and diamond.

The vertical element is configured to cause a main current to flow in the thickness direction of the semiconductor substrate 41 (semiconductor element 40), that is, in the Z direction. The vertical element of the present embodiment is the IGBT12 and the diode 13 constituting one arm. The vertical element is an IGBT in which diodes are connected in antiparallel, that is, an RC-IGBT. RC is an abbreviation for Reverse Conducting. The vertical element is a heating element that generates heat when energized. A gate electrode (not shown) is formed on the semiconductor substrate 41. The gate electrode has, for example, a trench structure.

As shown in FIG. 5, the semiconductor substrate 41 has a substantially rectangular shape in plan view. The semiconductor substrate 41 includes an active region 411 and an outer peripheral region 412. The active region 411 is a formation region of the vertical element. The active region 411 may be referred to as a main region, a main cell region, a cell region, an element region, an element formation region, or the like. The active region 411 has, for example, a substantially rectangular planar shape. The active region 411 is aligned with the pad 44 in the Y direction. Plural cells (unit structure) are provided in the active region 411. The cells are connected in parallel to each other to form an RC-IGBT. The outer peripheral region 412 surrounds the active region 411 in the plan view. The outer peripheral region 412 has a substantially rectangular annular shape. A withstand voltage structure (not shown) such as a guard ring is formed in the outer peripheral region 412.

The semiconductor substrate 41 has one surface 41a and a back surface 41b as a plate surface on which the main electrode is provided. The one surface 41a of the semiconductor substrate 41 is adjacent to the one surface 30a of the sealing body 30. The back surface 41b is opposite to the one surface 41a in the thickness direction. The emitter electrode 42, which is one of the main electrodes, is disposed on the one surface 41a of the semiconductor substrate 41. The collector electrode 43, which is another main electrode, is disposed on the back surface 41b of the semiconductor substrate 41.

When the IGBT12 is turned on, a current (main current) flows between the main electrodes, that is, between the emitter electrode 42 and the collector electrode 43. The emitter electrode 42 also serves as an anode electrode of the diode 13. The collector electrode 43 also serves as a cathode electrode of the diode 13. The collector electrode 43 is formed on almost the entire back surface 41b of the semiconductor substrate 41. The emitter electrode 42 is formed on a part of the one surface 41a of the semiconductor substrate 41. The emitter electrode 42 corresponds to a first main electrode, and the collector electrode 43 corresponds to a second main electrode.

The pad 44 is an electrode for a signal. The pad 44 is formed in a region different from the emitter electrode 42 on the one surface 41a of the semiconductor substrate 41. The pad 44 is formed at an end of the semiconductor substrate 41 opposite to the formation region of the emitter electrode 42 in the Y direction. The pad 44 is provided side by side with the emitter electrode 42 in the Y direction. The number of pads 44 is not particularly limited. The pad 44 includes at least a pad 44G for a gate electrode.

The semiconductor element 40 of the present embodiment has five pads 44. In addition to the pad 44G, the semiconductor element 40 has, as the pad 44, a pad for detecting an emitter potential, a pad for detecting a cathode potential of a temperature sensitive diode (not shown) included in the semiconductor element 40, a pad for detecting an anode potential, and a pad for current sensing. The five pads 44 are arranged in the X direction.

As shown in FIGS. 5 and 6, the semiconductor element 40 includes a protective film 45 disposed on the one surface 41a of the semiconductor substrate 41. The protective film 45 is an insulating film provided on the one surface 41a of the semiconductor substrate 41 so as to cover the emitter electrode 42, specifically, a peripheral portion of a base layer 422 described later. As a material of the protective film 45, for example, polyimide, a silicon nitride film, or the like can be adopted.

The protective film 45 has an opening 451, 452. The opening 451, 452 is a through hole that penetrates the protective film 45 in the Z direction. The opening 451 defines a region where the emitter electrode 42 can be bonded to the conductive spacer 70. The opening 451 is provided so as to overlap with the emitter electrode 42 in a plan view. The opening 451 substantially coincides with the active region 411 in a plan view. The opening 452 defines a bonding region of the pad 44 with the bonding wire 90. The opening 452 is provided on the outer peripheral region 412 in a plan view. The protective film 45 has five openings 452. The protective film 45 covers a region excluding the opening 451, 452 in a plan view. The protective film 45 is disposed on the outer peripheral region 412.

The emitter electrode 42 includes a bonding portion 421 that is exposed from the opening 451 of the protective film 45 and provides a bonding region with the conductive spacer 70. In a plan view, the outer contour of the bonding portion 421 coincides with the outer contour of the opening 451. The bonding portion 421 is disposed on the active region 411 of the semiconductor substrate 41. The emitter electrode 42 has a multilayer structure. The emitter electrode 42 includes a base layer 422 and an upper layer 423. The pad 44 also has a multilayer structure similar to that of the emitter electrode 42.

The base layer 422 is a metal layer disposed adjacent to the semiconductor substrate 41, in the emitter electrode 42 having a multilayer structure. The base layer 422 is formed using a material containing Al (aluminum) as a main component. The base layer 422 of the present embodiment is an Al alloy such as AlSi or AlSiCu. The base layer 422 may be referred to as an Al layer, a first metal layer, a base electrode, a wiring electrode, or the like.

The base layer 422 extends over the outer peripheral region 412 while including the active region 411 in a plan view. The base layer 422 is connected to the emitter and the anode of the vertical element. The base layer 422 has a peripheral portion 4221 surrounding the bonding portion 421 in a plan view. The peripheral portion 4221 may be referred to as an outer peripheral portion. In the present embodiment, the entire region of the peripheral portion 4221 overlaps with the protective film 45 in a plan view. The protective film 45 is disposed on the one surface 41a of the semiconductor substrate 41 so as to cover the entire peripheral portion 4221 of the base layer 422.

The upper layer 423 is stacked on the base layer 422 for the purpose of improving the bonding strength with the solder 91, improving the wettability with respect to the solder 91, and the like. The upper layer 423 is formed using a material containing Ni (nickel) as a main component. The upper layer 423 of the present embodiment is NiP deposited by an electroless plating method. The upper layer 423 is a Ni plating film containing P. The upper layer 423 may be referred to as a Ni layer, a second metal layer, a plating layer, an upper electrode, a connection electrode, or the like.

In the manufacturing process, an Au layer may be further provided on the upper layer 423. Au suppresses oxidation of Ni and improves wettability with the solder 91. Since Au diffuses into the solder during soldering, Au exists in a state before bonding and does not exist in a bonded state.

The upper layer 423 is arranged on the base layer 422 and exposed from the opening 451. The upper layer 423 of the present embodiment is disposed on the base layer 422 in the opening 451. The outer peripheral end portion of the upper layer 423 is in contact with the wall surface of the protective film 45 defining the opening 451.

The wiring member 50 is electrically connected to the emitter electrode 42 and provides a wiring function. Similarly, the wiring member 60 is electrically connected to the collector electrode 43 and provides a wiring function. The semiconductor element 40 is supported between the wiring member 50 and the wiring member 60 in the Z direction. The wiring member 50 and the wiring member 60 are disposed so as to at least partially face each other in the Z direction. The wiring member 50, 60 encloses the semiconductor element 40 in a plan view. The wiring member 50 corresponds to a first wiring member, and the wiring member 60 corresponds to a second wiring member.

The wiring member 50, 60 provides a heat dissipation function of dissipating heat generated by the semiconductor element 40. The wiring member 50, 60 may be referred to as a heat dissipation plate, a heat sink, or the like. The wiring member 50, 60 of the present embodiment is a metal plate made of a metal having good conductivity such as Cu or a Cu alloy. The metal plate is provided, for example, as part of a lead frame. Instead of the metal plate, a substrate in which metal bodies are disposed on both surfaces of an insulating base material may be adopted. The wiring member 50, 60 may include a plating film of Ni, Au, or the like on the surface thereof.

The wiring member 50 includes a facing surface 50a adjacent to the semiconductor element 40, and a back surface 50b opposite to the facing surface 50a. Similarly, the wiring member 60 has a facing surface 60a and a back surface 60b. The wiring member 50, 60 has, for example, a substantially rectangular shape in plan view. The back surface 50b, 60b may be referred to as a heat dissipation surface, an exposed surface, or the like. The back surface 50b, 60b of the present embodiment is exposed from the sealing body 30. The back surface 50b of the wiring member 50 is substantially flush with the one surface 30a of the sealing body 30. The back surface 60b of the wiring member 60 is substantially flush with the back surface 30b of the sealing body 30.

The conductive spacer 70 is interposed between the semiconductor element 40 and the wiring member 50. The conductive spacer 70 provides a spacer function of securing a predetermined interval between the semiconductor element 40 and the wiring member 50. For example, the conductive spacer 70 secures a height for electrically connecting the corresponding signal terminal 83 to the pad 44 of the semiconductor element 40 via the bonding wire 90. The conductive spacer 70 is positioned in the middle of an electrical conduction and thermal conduction path between the emitter electrode 42 of the semiconductor element 40 and the wiring member 50, and provides a wiring function and a heat dissipation function.

The conductive spacer 70 includes a metal material having good electrical and thermal conductivity such as Cu. The conductive spacer 70 may include a plating film on a face thereof. The conductive spacer 70 may be referred to as a terminal, a terminal block, or a metal block body. The conductive spacer 70 of the present embodiment is a columnar body having a substantially rectangular planar shape. In plan view, the outer contour of the conductive spacer 70 is slightly smaller than the outer contour of the bonding portion 421 of the emitter electrode 42 in plan view. The conductive spacer 70 has an end surface 70a facing the semiconductor element 40 and an end surface 70b facing the wiring member 50. The end surface 70a corresponds to a first terminal surface, and the end surface 70b corresponds to a second terminal surface.

The external connection terminal 80 electrically connects the semiconductor device 20 to an external device. The external connection terminal 80 is formed using a metal material having good conductivity such as copper. The external connection terminal 80 is, for example, a plate member. The external connection terminal 80 may be referred to as a “lead”. The external connection terminal 80 includes a main terminal 81, 82 and a signal terminal 83. The main terminal 81, 82 of the external connection terminal 80 is electrically connected to the main electrode of the semiconductor element 40.

The main terminal 81 is electrically connected to the emitter electrode 42. The main terminal 81 may be referred to as an emitter terminal. The main terminal 81 is connected to the emitter electrode 42 via the wiring member 50. The main terminal 81 is continuous with one end of the wiring member 50 in the Y direction. The thickness of the main terminal 81 is smaller than that of the wiring member 50. The main terminal 81 is connected to the wiring member 50 so as to be substantially flush with the facing surface 50a. The main terminal 81 may be connected to the wiring member 50 by being continuously and integrally provided, or may be provided as a separate member and connected by bonding.

The main terminal 81 of the present embodiment is provided integrally with the wiring member 50 as a part of the lead frame. The main terminal 81 extends from the wiring member 50 in the Y direction and protrudes to the outside from the side surface 30c of the sealing body 30. The main terminal 81 has a bent portion in the portion covered with the sealing body 30, and protrudes from the side surface 30c at the vicinity of the center in the Z direction.

The main terminal 82 is electrically connected to the collector electrode 43. The main terminal 82 may be referred to as a collector terminal. The main terminal 82 is connected to the collector electrode 43 via the wiring member 60. The main terminal 82 is continuous with one end of the wiring member 60 in the Y direction. The thickness of the main terminal 82 is smaller than that of the wiring member 60. The main terminal 82 is connected to the wiring member 60 so as to be substantially flush with the facing surface 60a. The main terminal 82 may be connected to the wiring member 60 by being continuously and integrally provided, or may be provided as a separate member and connected by bonding.

The main terminal 82 of the present embodiment is provided integrally with the wiring member 60 as a part of a lead frame separate from the main terminal 81. The main terminal 82 extends from the wiring member 60 in the Y direction and protrudes to the outside from the side surface 30c. The main terminal 82 has a bent portion in the middle of the portion covered by the sealing body 30, and protrudes from the side surface 30c at the vicinity of the center in the Z direction. The main terminals 81 and 82 are arranged side by side in the X direction so that the side surfaces face each other.

The signal terminal 83 is electrically connected to the corresponding pad 44 of the semiconductor element 40. The signal terminal 83 is electrically connected to the pad 44 via the bonding wire 90. The signal terminal 83 extends in the Y direction and protrudes outward from the side surface 30d of the sealing body 30. The semiconductor device 20 of the present embodiment includes five signal terminals 83 corresponding to the pads 44. The signal terminals 83 are arranged side by side in the X direction. The signal terminal 83 is configured in a lead frame common to the wiring member 60 and the main terminal 82. The signal terminals 83 are electrically separated from each other by cutting a tie bar (not shown).

The solder 91 is interposed between the bonding portion 421 of the emitter electrode 42 of the semiconductor element 40 and the end surface 70a of the conductive spacer 70, and joins the emitter electrode 42 and the conductive spacer 70. The solder 91 may be referred to as on-element solder. The solder 92 is interposed between the end surface 70b of the conductive spacer 70 and the facing surface 50a of the wiring member 50, and joins the conductive spacer 70 and the wiring member 50. The solder 92 may be referred to as on-spacer solder. The solder 93 is interposed between the collector electrode 43 of the semiconductor element 40 and the facing surface 60a of the wiring member 60, and joins the collector electrode 43 and the wiring member 60. The solder 93 may be referred to as under-element solder.

The solders 91, 92, and 93 may be made of a common material or different materials. As an example, the solder 91, 92, 93 of the present embodiment is multicomponent lead-free solder containing Cu, Bi, Sb, and the like, and the remainder being Sn.

In the semiconductor device 20, the semiconductor element 40 constituting one arm is sealed by the sealing body 30. The sealing body 30 integrally seals the semiconductor element 40, a part of the wiring member 50, a part of the wiring member 60, the conductive spacer 70, and a part of the external connection terminal 80.

The semiconductor element 40 is disposed between the wiring member 50 and the wiring member 60 in the Z direction. The semiconductor element 40 is supported between the wiring member 50 and the wiring member 60 arranged to face each other. Thereby, the heat of the semiconductor element 40 can be dissipated to both sides in the Z-direction. The semiconductor device 20 has a double-sided heat dissipation structure. The back surface 50b of the wiring member 50 is substantially flush with the one surface 30a of the sealing body 30. The back surface 60b of the wiring member 60 is substantially flush with the back surface 30b of the sealing body 30. Since the back surface 50b, 60b is an exposed surface, it is possible to enhance the heat dissipation.

### Manufacturing Method

Next, an example of a method of manufacturing the semiconductor device 20 will be described. First, components of the semiconductor device 20 are prepared. Specifically, the semiconductor element 40, the wiring member 50, 60, the conductive spacer 70, and the external connection terminal 80 are prepared.

Next, molten solder is applied to form a connected body. A molten solder (solder 93) is disposed between the wiring member 60 and the collector electrode 43 of the semiconductor element 40. A molten solder (solder 91) is disposed between the emitter electrode 42 and the conductive spacer 70. A molten solder (solder 92) is disposed on the conductive spacer 70. By solidifying the molten solder, the wiring member 60, the semiconductor element 40, and the conductive spacer 70 are stacked, and a connected body integrally connected is obtained.

The molten solder can be applied using, for example, a transfer method. For example, a molten solder (solder 93) is applied to the facing surface 60a of the wiring member 60. A molten solder (solder 91) is applied to the end surface 70a of the conductive spacer 70. A molten solder (solder 92) is applied onto the end surface 70b of the conductive spacer 70. As described above, in the present embodiment, the semiconductor device 20 is formed using the solder die bonding method.

Next, the pad 44 of the semiconductor element 40 and the signal terminla 83 are connected by the bonding wire 90.

Next, the wiring member 50 and the conductive spacer 70 are connected by reflow. For example, the wiring member 50 is disposed on a pedestal (not shown) so that the facing surface 50a is on the upper side. Then, the connected body is stacked on the wiring member 50 so that the solder 92 faces the facing surface 50a of the wiring member 50, and reflow is performed. In the reflow, a load is applied in the Z direction from the wiring member 60 so that the height of the semiconductor device 20 becomes a predetermined height.

A heat source (not shown) used for reflow of the solder is disposed, for example, on a surface of the pedestal opposite to the placement surface. In this arrangement, the heat of the heat source is transferred to the solder 92 via the pedestal and the wiring member 50.

The solder 92 is melted by heat from the heat source, and the wiring member 50 and the conductive spacer 70 are connected (joined). That is, the emitter electrode 42 and the wiring member 50 are electrically connected to each other. The heat from the heat source is also transferred to the solder 91 via the conductive spacer 70. As a result, the solder 91 is also melted. Similarly, the solder 93 may also be melted.

Next, the sealing body 30 is formed. Although not illustrated, in the present embodiment, the sealing body 30 is molded by a transfer molding method. The sealing body 30 is molded so as to completely cover the wiring member 50, 60, and cutting is performed after the molding. The sealing body 30 is cut together with a part of the wiring member 50, 60. Thus, the back surface 50b, 60b is exposed. The back surface 50b is substantially flush with the back surface 30b, and the back surface 60b is substantially flush with the back surface 30b.

Next, unnecessary portions of the lead frame such as tie bars and an outer peripheral frame are removed, whereby the semiconductor device 20 can be obtained.

In this embodiment, the solder die bonding method is used, but it is not limited. For example, a solder foil may be used. Alternatively, the sealing body 30 may be molded in a state in which the back surface 50b, 60b is pressed against the cavity wall surface of the molding die and brought into close contact with the cavity wall surface. In this case, at the time of molding the sealing body 30, the back surface 50b, 60b is exposed from the sealing body 30. This eliminates the need for cutting after molding.

### Solder Overflow

As shown in FIG. 5, the bonding portion 421 of the emitter electrode 42 and the pad 44 are arranged in the Y direction. That is, the bonding portion 421 is provided to be biased to one side in the Y direction. Therefore, when the above-described connected body is formed, the semiconductor element 40 is connected in such a manner that the end adjacent to the bonding portion 421 sinks and the end adjacent to the pad 44 rises due to the weight of the conductive spacer 70.

Then, reflow is performed in a state in which the semiconductor element 40 is connected to the wiring member 60 in the inclined manner. As described above, heat from the heat source is also transmitted to the solder 91 via the wiring member 50 and the conductive spacer 70. Due to the inclination of the semiconductor element 40, the end adjacent to the pad 44 is closer to the wiring member 50 than the end adjacent to the bonding portion 421. Therefore, the solder 91 is melted first in the vicinity of the pad 44. Further, due to the inclination, the end adjacent to the pad 44 is closer to the pedestal than the end adjacent to the bonding portion 421, that is, positioned vertically downward. Therefore, there is a possibility that the solder 91 overflows from the bonding portion 421 toward the pad 44 in the Y direction. Even if the inclination does not occur, when the amount of the applied solder 91 is large, the excess solder may overflow toward the pad 44.

When the solder 91 reaches the pad 44, a short circuit of the pad 44 occurs. Therefore, it is desirable to suppress the overflow of the solder 91 toward the pad 44.

### Short Circuit Suppression Structure

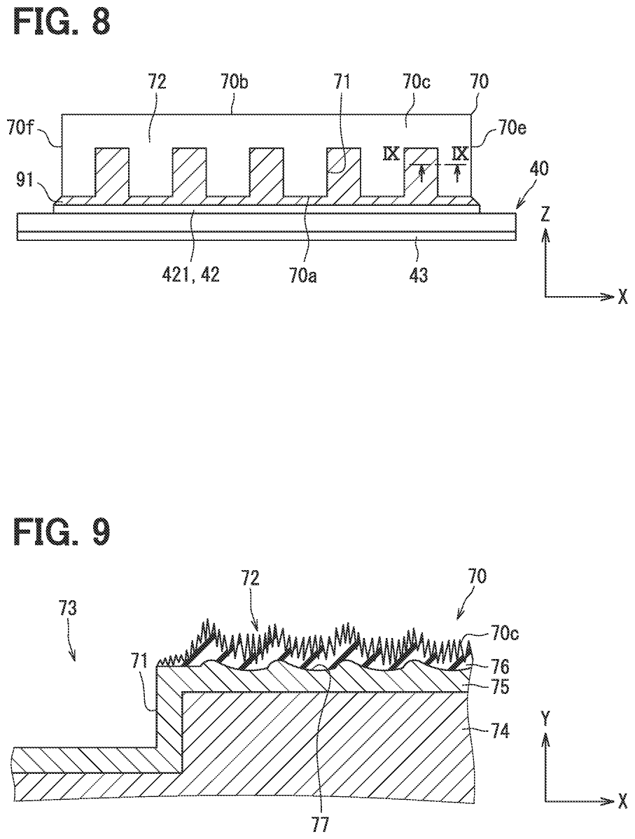

Next, a structure for suppressing solder overflow to the pad 44, that is, a structure for suppressing a short circuit of the pad 44 will be described with reference to FIGS. 7 to 9. FIG. 7 is a partial sectional view taken along a line VII-VII of FIG. 4. FIG. 7 shows a state in which the conductive spacer 70 is disposed on the semiconductor element 40 shown in FIG. 5, and the solder 91 is omitted. FIG. 8 is a side view of FIG. 7 as viewed from the arrow direction Y1. In FIG. 8, the solder 91 is hatched for clarity. FIG. 8 illustrates, as an example, a state in which the overflowing solder 91 is received by the recess 71. FIG. 9 is a sectional view taken along a line IX-IX of FIG. 8. In FIG. 9, the solder 91 is omitted for convenience.

As shown in FIGS. 7 and 8, the conductive spacer 70 has a recess 71. The recess 71 is provided in at least a portion of the side surface of the conductive spacer 70 adjacent to the pad 44. The recess 71 is recessed with respect to a peripheral portion of the recess in the side surface. The recess 71 is open at least in the end surface 70a. The recess 71 is formed by press working, for example.

As described above, the conductive spacer 70 of the present embodiment is a columnar body having a substantially rectangular planar shape. The conductive spacer 70 has four side surfaces 70c, 70d, 70e, and 70f. In the present embodiment, the recess 71 is provided only on the side surface 70c adjacent to the pad 44. The recess 71 is not provided on the side surface 70d, 70e, 70f. As shown in FIGS. 7 and 8, the conductive spacer 70 has five recesses 71 on the side surface 70c.

In each of the recesses 71, one end is open to the end surface 70a, and the other end is closed. The recess 71 extends from the end surface 70a to a predetermined position between the end surface 70a and the end surface 70b. The recess 71 extends in the Z direction with a substantially constant width and depth. The width is a length in a direction parallel to the surface on which the recess 71 is formed and orthogonal to the extending direction of the recess 71. The depth is a length in a direction orthogonal to the surface on which the recess 71 is formed. As shown in FIG. 7, each of the recesses 71 is provided so as to be aligned with the corresponding pad 44 in the Y direction.

The side surface of the conductive spacer 70 has a roughened region 72 in which a roughened oxide film 76 is formed, and a non-roughened region 73 in which the roughened oxide film 76 is not formed. A portion of the side surface of the conductive spacer 70 is the roughened region 72, and the remaining portion is the non-roughened region 73. The roughened region 72 is a region of the side surface of the conductive spacer 70 which is roughened by laser. The non-roughened region 73 is a region of the side surface that is not roughened by the laser. The non-roughened region 73 has higher wettability to solder than the roughened region 72.

As shown in FIG. 9, the conductive spacer 70 includes a base material 74, and a metal film 75 and the roughened oxide film 76 provided on the surface of the base material 74. The base material 74 forms a main portion of the conductive spacer 70. The base material 74 is formed using copper-related material. The metal film 75 includes a material having higher wettability to solder than the base material 74. The metal film 75 is formed on the entire region of the side surface. The metal film 75 according to the present embodiment is formed over the entire region of the surface of the base material 74. The roughened oxide film 76 is formed locally on the side surface.

The roughened oxide film 76 is locally formed on the metal film 75 on the side surface by irradiating the metal film 75 with laser light. The metal film 75 has a lower base film mainly made of nickel (Ni) and an upper base film mainly made of gold (Au). In the present embodiment, an electroless nickel-plated film including phosphorus (P) is adopted as the lower base film. The upper base film (mainly made of Au) in a portion of the metal film 75 exposed from the roughened oxide film 76 in contact with the solder diffuses into the solder during the reflow. The upper base film (mainly made of Au) in a portion of the metal film 75 where the roughened oxide film 76 is formed is removed by the irradiation of the laser beam at the time of forming the roughened oxide film 76. The roughened oxide film 76 is an oxide film mainly made of nickel (Ni). In the present embodiment, NI₂O₃, NiO, and Ni constitute 80%, 10%, and 10%, respectively, of the roughened oxide film 76.

A dent 77 is formed on the surface of the metal film 75 by irradiation of pulsed laser light. One dent 77 is formed per pulse. The roughened oxide film 76 is formed by melting, vaporizing, and depositing a face layer portion of the metal film 75 by irradiation of laser light. The roughened oxide film 76 is an oxide film derived from the metal film 75. The roughened oxide film 76 is mainly made of metal (Ni) as the main component of the metal film 75. The roughened oxide film 76 is formed to follow the recesses and protrusions of the surface of the metal film 75 having the dent 77. On the surface of the roughened oxide film 76, recesses and protrusions are formed at a pitch finer than the width of the dent 77. In other words, the extremely fine recesses and protrusions (a roughened portion) are formed.

A region on the side surface of the conductive spacer 70 where the roughened oxide film 76 is formed is the roughened region 72. A region on the side surface where the roughened oxide film 76 is not formed, that is, where the metal film 75 is exposed is the non-roughened region 73. As shown in FIG. 9, the roughened oxide film 76 is formed in a region of the side surface of the conductive spacer 70 except for the inner surface of the recess 71. The roughened oxide film 76 is not formed on the inner surface (wall surface) of the recess 71 among the side surfaces of the conductive spacer 70. The roughened region 72 is provided on the side surface except for the inner surface of the recess 71. The non-roughened region 73 is provided on the inner surface of the recess 71. The end surface 70a, 70b is a region where the roughened oxide film 76 is not formed.

According to the present embodiment, the recess 71 that opens to the end surface 70a is provided at least at a portion of the side surface of the conductive spacer 70 adjacent to the pad 44 in a plan view. In the side surface, the inner surface of the recess 71 is defined as the non-roughened region 73, and a region other than the inner surface of the recess 71 is defined as the roughened region 72 by the roughened oxide film 76. The oxide film (the roughened oxide film) has lower wettability to the solder as compared with the metal film. Since the roughened oxide film has fine protrusions and recesses at the surface, the contact area with the solder is reduced and a part of the solder is formed into a spherical shape due to surface tension. In other words, the contact angle becomes large. As a result, the wettability of the roughened oxide film to the solder is low.

Therefore, if the solder 91 overflows from the bonding portion 421 of the emitter electrode 42 toward the pad 44 at the time of reflow, the solder wets and spreads to the non-roughened region 73 of the side surface provided adjacent to the pad and is received in the recess 71. Accordingly, it is possible to suppress the overflowing solder 91 from reaching the pad 44. As a result, it is possible to provide the semiconductor device 20 capable of suppressing a short circuit of the pad 44. For example, the occurrence of a short circuit between the pad 44 and the emitter electrode 42 can be suppressed. The occurrence of a short circuit between the pads 44 can be suppressed.

In addition, the protrusion height of the solder 91 from the side surface 70c can be suppressed by receiving the solder 91 overflowing into the recess 71. Accordingly, it is possible to suppress the overflowing solder 91 from coming into contact with the bonding wire 90.

In addition, a portion of the side surface of the conductive spacer 70 excluding the inner surface of the recess 71 is the roughened region 72. The roughened oxide film 76 is formed in the roughened region 72. As described above, the wettability of the roughened oxide film 76 with respect to the solder 91 is lower than that of the metal film 75. Therefore, the solder 91 does not wet and spread in the roughened region 72. On the other hand, very fine irregularities are formed on the surface of the roughened oxide film 76, and the sealing body 30 is entangled to produce an anchor effect. The contact area with the sealing body 30 increases. Therefore, the adhesion to the sealing body 30 can be increased.

The recess 71 of the present embodiment is opened only in the end surface 70a adjacent to the semiconductor element 40, not the end surface 70b of the conductive spacer 70. As shown in FIG. 8, the recess 71 extends from the end surface 70a to a predetermined position between the end surface 70a and the end surface 70b. Accordingly, the formation region of the recess 71 can be reduced, that is, the thermal resistance by the conductive spacer 70 can be reduced. Therefore, it is possible to efficiently dissipate the heat of the semiconductor element 40 while suppressing the solder 91 from overflowing toward the pad 44.

### Modification

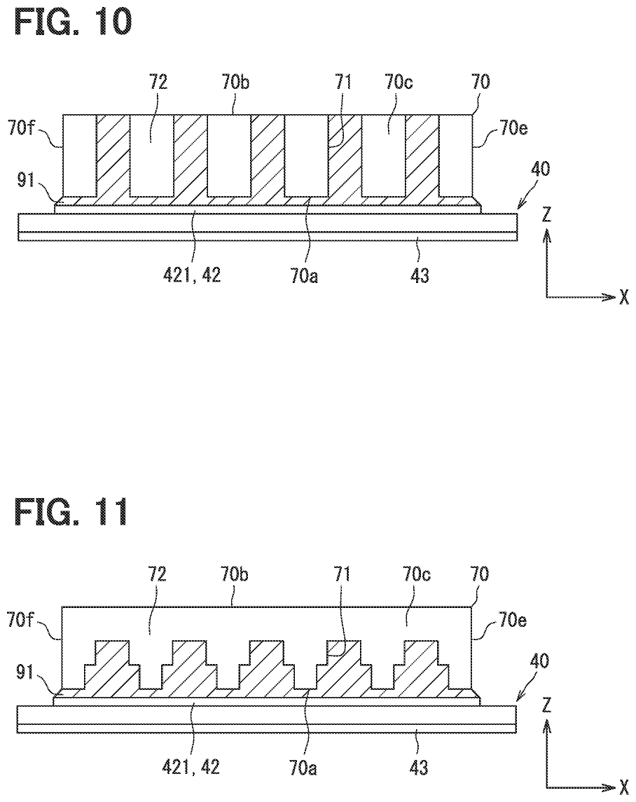

As shown in FIG. 10, the recess 71 may communicate with the end surface 70a and the end surface 70b of the conductive spacer 70. FIG. 10 corresponds to FIG. 8. The recess 71 extends from the end surface 70a to the end surface 70b. The recess 71 at one end is open to the end surface 70a, and the recess 71 at the other end is open to the end surface 70b. According to this, the amount of the solder 91 that can be kept in the recess 71 can be increased. It is also possible to release the overflowing solder 91 onto the end surface 70b.

The number, arrangement, and shape of the recesses 71 are not limited to the examples described above. The number of recesses 71 may be greater or smaller than the number of pads 44. In the present embodiment, as shown in FIG. 7, the same number of recesses 71 as the number of pads 44 are provided. Since each of the recesses 71 is aligned with the corresponding pad 44 in the Y direction, it is possible to effectively restrict the solder 91 from overflowing toward the pad 44.

The recess 71 and the non-roughened region 73 may be provided in at least one of the side surfaces 70d, 70e, and 70f in addition to the side surface 70c. For example, the recess 71 and the non-roughened region 73 may be provided on the side surface 70d, similar to those on the side surface 70c. According to this, the solder 91 overflowing away from the pad 44 in the Y direction can be received in the recess 71 provided in the side surface 70d. In addition, it is possible to restrict the position of the conductive spacer 70 from deviating from the bonding portion 421 of the emitter electrode 42. The recess 71 and the non-roughened region 73 may be provided on all the side surfaces 70c, 70d, 70e, 70f. In the present embodiment, the recess 71 and the non-roughened region 73 are provided only on the side surface 70c. Accordingly, a short circuit of the pad 44 can be suppressed. In addition, an increase in the thermal resistance of the conductive spacer 70 due to the recess 71 can be suppressed.

The shape of the recess 71 is not limited to the example described above. The width and the depth of the recess 71 are not limited to be constant. The width of the recess 71 may be different between the end adjacent to the end surface 70a and the end adjacent to the end surface 70b. For example, in FIG. 11, the width of the recess 71 at a first position in the Z direction is equal to or greater than the width of the recess 71 at a second position farther from the end surface 70a than the first position. The width at the end adjacent to the end surface 70a (semiconductor element 40) is larger than that at the end adjacent to the end surface 70b (wiring member 50). The width of the recess 71 is a first width in a range from the end surface 70a to a predetermined position, and is a second width narrower than the first width in a range from the predetermined position toward the end surface 70b. The depth of the recess 71 is constant. According to the above configuration, since the width adjacent to the semiconductor element 40 is large, the solder 91 easily wets and spreads in the recess 71. FIG. 11 corresponds to FIG. 8.

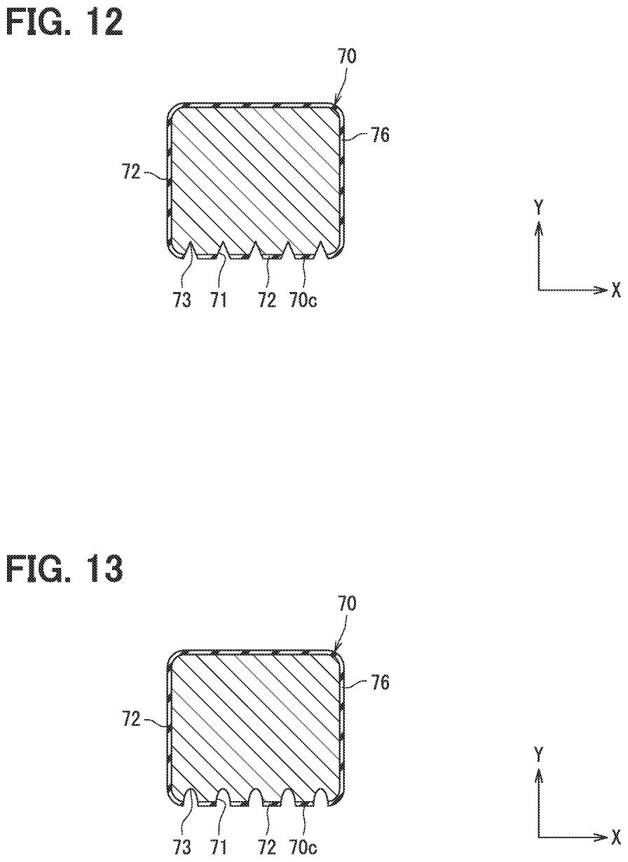

The recess 71 having the shape shown in FIG. 11 may be provided so as to open to the end surface 70b. Similarly to the width, the depth of the recess 71 may be different between the end adjacent to the end surface 70a and the end adjacent to the end surface 70b. The depth adjacent to the end surface 70a may be deeper than the depth adjacent to the end surface 70b. The shape of the recess 71 in the cross section is a substantially rectangular shape (see FIG. 7), but is not limited thereto. For example, as illustrated in FIG. 12, the shape may be a substantially triangular shape. As shown in FIG. 13, the recess 71 may have a curved inner surface. The conductive spacer 70 shown in FIGS. 12 and 13 corresponds to FIG. 7.

The conductive spacer 70 has a substantially rectangular planar shape, but is not limited thereto. The recess 71 may be provided in at least a portion of the side surface of the conductive spacer 70 adjacent to the pad 44.

### Second Embodiment

This embodiment is a modification based on the preceding embodiment, and the description of the preceding embodiment can be incorporated. In the preceding embodiment, the recess is provided on the side surface of the conductive spacer, and the inner surface of the recess is set as the non-roughened region. Alternatively, a dummy wiring may be provided on the surface of the semiconductor element.

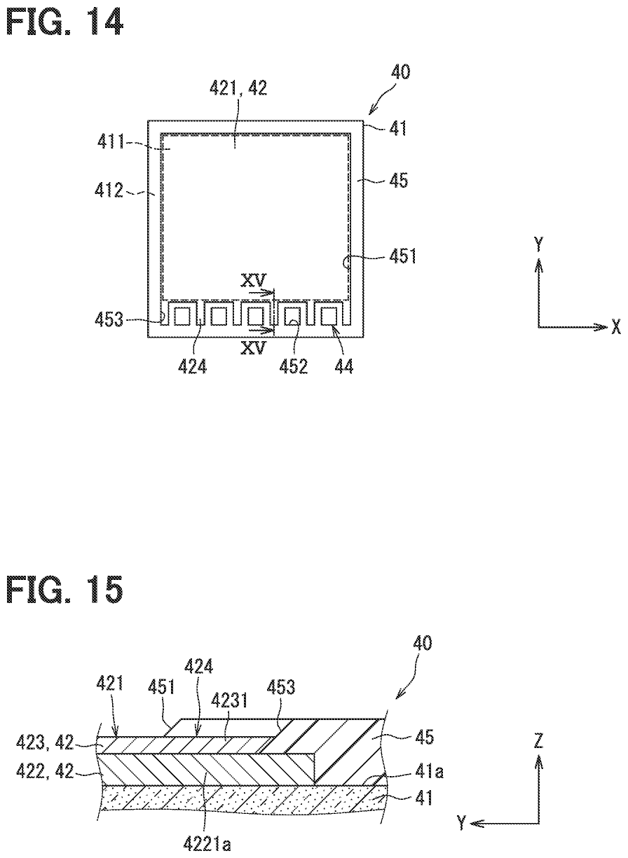

FIG. 14 is a plan view showing the semiconductor element 40 in the semiconductor device 20 according to the present embodiment. The semiconductor element 40 includes a dummy wiring connected to the bonding portion 421 of the emitter electrode 42. The dummy wiring extends in the Y direction from the end of the bonding portion 421 adjacent to the pad 44, and is arranged in parallel with the pad 44 in the X direction. The Y direction corresponds to a first direction, and the X direction corresponds to a second direction. The dummy wiring does not provide an electrical connection function. The dummy wiring provides a function of receiving the overflowing solder 91.

The semiconductor element 40 of the present embodiment includes the dummy wiring 424 using a component of the emitter electrode 42. The semiconductor element 40 includes plural dummy wirings 424. The dummy wirings 424 and the pads 44 are alternately arranged in the X direction. The dummy wiring 424 is located on both sides of the pad 44 in the X direction. Some of the dummy wirings 424 extend to between the adjacent pads 44.

FIG. 15 is a cross-sectional view taken along a line XV-XV of FIG. 14. As shown in FIGS. 14 and 15, the protective film 45 has a dummy opening 453. The dummy opening 453 is continuous with the opening 451 (main opening) and extends in the Y direction from the end of the opening 451 adjacent to the pad 44. The dummy opening 453 is an opening that defines the dummy wiring 424.

The thickness of the base layer 422 is substantially constant over the entire region. As in the preceding embodiment, the base layer 422 has a peripheral portion 4221 surrounding the bonding portion 421 in a plan view. The peripheral portion 4221 of the present embodiment is partially extended with respect to the configuration described in the preceding embodiment. The peripheral portion 4221 extends in the Y direction corresponding to the formation region of the dummy wiring 424. The base layer 422 has an overlapping portion 4221a which overlaps with the dummy opening 453 in a plan view as a part of the peripheral portion 4221. The overlapping portion 4221a is provided so as to enclose the dummy opening 453 in a plan view.

The upper layer 423 includes an extension portion 4231. The extension portion 4231 is a portion of the upper layer 423 disposed in the dummy opening 453. The extension portion 4231 is continuous with a portion of the upper layer 423 forming the bonding portion 421. The extension portion 4231 is formed continuously and integrally with the other portion of the upper layer 423. The extension portion 4231 is disposed on the overlapping portion 4221a of the base layer 422 in the dummy opening 453. The outer peripheral end of the extension portion 4231 is in contact with the wall surface of the protective film 45 defining the dummy opening 453. The dummy wiring 424 includes a part of the peripheral portion 4221 of the base layer 422, that is, the overlapping portion 4221a, and the upper layer 423.

In the present embodiment, the recess 71 is not formed in the conductive spacer 70. Other configurations are the same as those of the preceding embodiment.

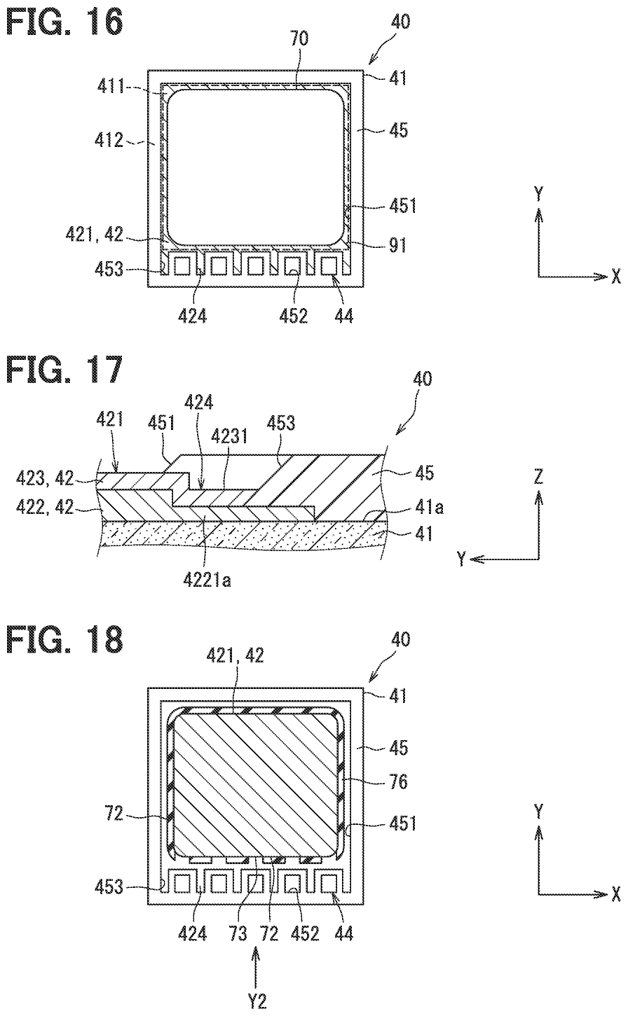

FIG. 16 is a partial sectional view showing a connection structure between the semiconductor element 40 and the conductive spacer 70 in the semiconductor device 20 of the present embodiment. FIG. 16 corresponds to FIG. 7. In FIG. 16, the solder 91 is hatched for clarity. FIG. 16 shows, as an example, a state in which the solder 91 wets and spreads to the end portion of the dummy wiring 424.

According to the present embodiment, if the solder 91 overflows from the bonding portion 421 of the emitter electrode 42 to the pad 44 during reflow, the solder wets and spreads to the dummy wiring 424 and is held on the dummy wiring 424. Accordingly, it is possible to restrict the overflowing solder 91 from wetting and spreading to the pad 44. As a result, it is possible to provide the semiconductor device 20 capable of suppressing a short circuit of the pad 44. For example, the occurrence of a short circuit between the pad 44 and the emitter electrode 42 can be suppressed. The occurrence of a short circuit between the pads 44 can be suppressed. In addition, it is possible to suppress the overflowing solder 91 from coming into contact with the bonding wire 90 by receiving the overflowing solder 91 in the dummy wiring 424.

In the present embodiment, the dummy wiring 424 extends from the bonding portion 421 of the emitter electrode 42 to between the pads 44. In this manner, the dummy wiring 424 is provided using the space between the pads 44. Therefore, the overflowing solder 91 can be received in the dummy wiring 424 while suppressing an increase in the size of the semiconductor element 40. Since the dummy wiring 424 extends to between the pads 44, it is possible to hold more overflowing solder 91.

In the present embodiment, the protective film 45 is provided with the dummy opening 453 extending in the Y direction from the opening 451 which is the main opening. The base layer 422 and the upper layer 423 extend to the position of the dummy opening 453. The dummy wiring 424 includes the overlapping portion 4221a overlapping with the dummy opening 453 in the base layer 422 and the extension portion 4231 disposed in the dummy opening 453 in the upper layer 423. Since the dummy wiring 424 is provided using the constituent elements of the emitter electrode 42, the configuration can be simplified as compared with a configuration in which a dummy wiring is separately provided.

### Modification

The thickness of the base layer 422 is substantially constant in the entire region, but it is not limited. As illustrated in FIG. 17, the thickness of the base layer 422 may be smaller in the portion overlapping with the dummy opening 453 than in the portion overlapping with the opening 451. The thickness of the overlapping portion 4221a of the base layer 422 is smaller than the thickness of the portion of the base layer 422 overlapping with the opening 451. Since the surface of the dummy wiring 424 is recessed with respect to the surface of the bonding portion 421, it is possible to receive more overflowing solder 91. In case where the base layer 422 is formed by stacking plural Al layers, the base layer 422 having a thin overlapping portion 4221a can be provided by partially disposing the upper layer.

The dummy wiring 424 is not limited to the above configuration. The dummy wiring may be provided separately from the element of the emitter electrode 42. For example, a dummy wiring may be provided on the protective film 45 so as to be continuous with the bonding portion 421 of the emitter electrode 42.

The configuration described in the present embodiment and the configuration described in the first embodiment may be combined. For example, the conductive spacer 70 having the recess 71 on the side surface 70c may be combined with the semiconductor element 40 having the dummy wiring 424. In the conductive spacer 70, the inner surface of the recess 71 is defined as the non-roughened region 73, and the side surface excluding the inner surface of the recess 71 is defined as the roughened region 72 having the roughened oxide film 76. By the combination, since the accommodation region of the excess solder increases, it is possible to more effectively suppress the short circuit of the pad 44.

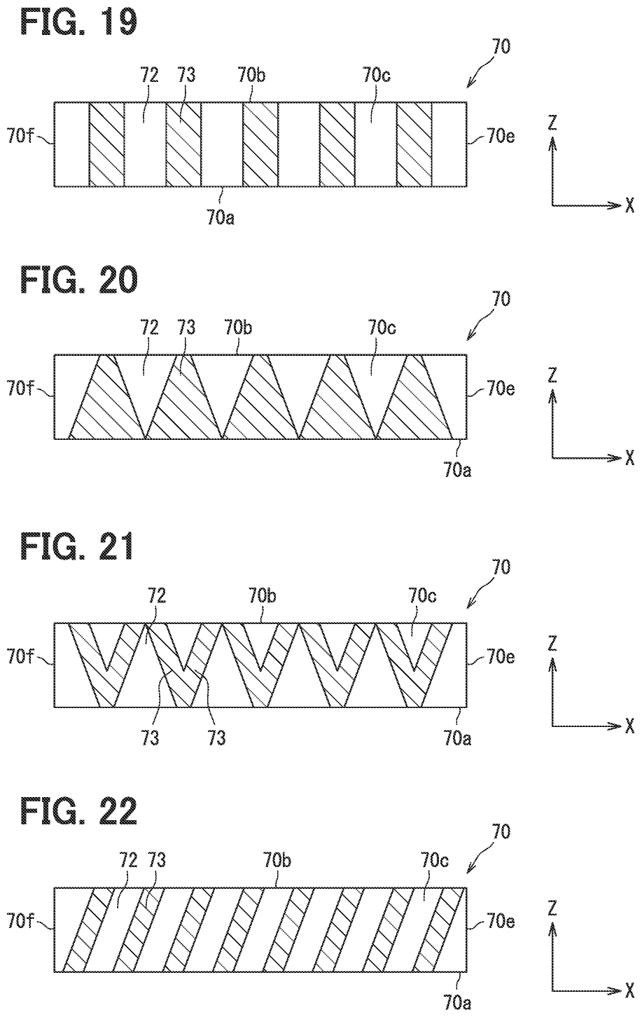

The conductive spacer 70 having the roughened region 72 and the non-roughened region 73 without the recess 71 may be combined with the configuration described in the present embodiment. For example, as shown in FIGS. 18 and 19, the non-roughened region 73 is provided only on the side surface 70c of the conductive spacer 70. FIG. 18 is a partial sectional view illustrating a connection structure between the semiconductor element 40 and the conductive spacer 70. FIG. 18 corresponds to FIG. 7. In FIG. 18, the solder 91 is omitted for convenience. FIG. 19 is a side view of the conductive spacer 70 viewed from the arrow direction Y2 of FIG. 18. In FIG. 19, metal hatching is applied to the non-roughened region 73 for clarity.

The non-roughened region 73 extends in the Z direction from the end surface 70a to the end surface 70b. The roughened region 72 having the roughened oxide film 76 and the non-roughened region 73 are alternately provided on the side surface 70c. The remaining side surfaces 70d, 70e, and 70f have the roughened region 72. According to the configuration illustrated in FIGS. 18 and 19, if the solder 91 overflows from the bonding portion 421 of the emitter electrode 42 toward the pad 44, the solder can be kept on the dummy wiring 424 and the non-roughened region 73. Therefore, the short circuit of the pad 44 can be effectively suppressed.

The arrangement pattern of the roughened region 72 and the non-roughened region 73 is not limited to the example illustrated in FIGS. 18 and 19. Due to the laser roughening, the degree of freedom of the pattern is high. For example, the width at the first position in the Z direction may be equal to or greater than the width at the second position farther from the end surface 70a, and the width of the end portion adjacent to the end surface 70a may be wider than the width of the end portion adjacent to the end surface 70b. As illustrated in FIG. 20, the width of the non-roughened region 73 is the maximum at the end adjacent to the end surface 70a, and the width becomes narrower toward the end surface 70b. With such a pattern, the overflowing solder 91 is likely to wet and spread on the side surface 70c of the conductive spacer 70. Therefore, the short circuit of the pad 44 can be more effectively suppressed.

As shown in FIG. 21, the non-roughened region 73 branching in two directions from the end surface 70a may be provided. The non-roughened region 73 has a substantially V shape in a plan view seen in the Y direction. The substantially V-shaped non-roughened regions 73 are repeatedly provided in the X direction. With such a pattern, the overflowing solder 91 can be released in two directions due to the V-shaped non-roughened region 73. As a result, the amount of the solder 91 received in one place can be reduced, so that the solder 91 can be restricted from coming into contact with the bonding wire 90.

As shown in FIG. 22, the non-roughened region 73 having a constant width may be provided to be inclined relative to the Z direction. The non-roughened region 73 extends in a direction inclined at a predetermined angle with respect to the Z direction. The roughened regions 72 are arranged in the X direction at a predetermined pitch. In the two adjacent roughened regions 72, there is no gap in the X direction between the end of the first roughened region 72 adjacent to the end surface 70a and the end of the second roughened region 72 adjacent to the end surface 70b. With such a pattern, since there are the roughened regions 72 in the X direction, it is possible to increase the adhesion force with the sealing body 30 in the entire peripheral direction of the side surface 70c. For example, in a case where the roughened region 72 and the non-roughened region 73 are provided in the same pattern on the entire periphery of the side surface, the adhesion force with the sealing body 30 can be increased on the entire periphery of the side surface.

FIGS. 20, 21, and 22 correspond to FIG. 19. In FIGS. 20, 21, and 22, the non-roughened region 73 is hatched to represent metal for clarity.

### Other Embodiments

The disclosure in this specification, the drawings, and the like is not limited to the exemplified embodiments. The disclosure encompasses the illustrated embodiments and modifications by those skilled in the art based thereon. For example, the disclosure is not limited to the combinations of components and/or elements shown in the embodiments. The disclosure may be implemented in various combinations. The disclosure may include additional portions that can be added to the embodiments. The disclosure includes those in which the components and/or elements of the embodiments are omitted. The disclosure includes the reallocation or combination of components and/or elements between one embodiment and another embodiment. The disclosed technical scope is not limited to the description of the embodiments. The several technical scopes disclosed are indicated by the description of the claims, and should be further understood to include meanings equivalent to the description of the claims and all modifications within the scope.

The disclosure in the specification, drawings and the like is not limited by the description of the claims. The disclosures in the specification, the drawings, and the like encompass the technical ideas described in the claims, and further extend to a wider variety of technical ideas than those in the claims. Thus, various technical ideas can be extracted from the disclosure of the specification, the drawings and the like without being limited to the description of the present disclosure.

When an element or layer is referred to as being “on,” “coupled,” “connected,” or “combined,” it may be directly on, coupled, connected, or combined to the other element or layer, or further, intervening elements or layers may be present. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatially relative terms such as “inner,” “outer,” “back,” “below,” “low,” “above,” and “high” are utilized herein to facilitate description of one element or feature's relationship to another element(s) or feature(s) as illustrated. Spatial relative terms can be intended to include different orientations of a device in use or operation, in addition to the orientations depicted in the drawings. For example, when the device in the figure is flipped over, an element described as “below” or “directly below” of the other element or feature is read as “above” of the other element or feature. Therefore, the term “below” can include both above and below. The device may be oriented in the other direction (rotated 90 degrees or in any other direction) and the spatially relative terms used herein are interpreted accordingly.

The vehicle drive system 1 is not limited to the above structure described in the embodiments. The vehicle drive system 1 includes one motor generator 3 in the embodiment, it is not limited to in the present disclosure. Plural motor generators may be provided. The power conversion device 4 is not limited to include the inverter 5 as the electric power conversion device. For example, plural inverters may be provided. At least one inverter and a converter may be provided. Only the converter may be provided.

The semiconductor device 20 is not limited to include only one semiconductor element 40 constituting one arm. The semiconductor device 20 may include plural semiconductor elements 40 constituting one arm. That is, the semiconductor elements 40 may be connected in parallel to each other to form one arm. The semiconductor device 20 may include plural semiconductor elements 40 constituting the upper and lower arm circuits 9 for one phase, or plural semiconductor elements 40 constituting the upper and lower arm circuits 9 for plural phases.

The back surface 50b, 60b of the wiring member 50, 60 is not limited to be exposed from the sealing body 30. At least one of the back surface 50b and the back surface 60b may be covered with the sealing body 30. At least one of the back surface 50b and the back surface 60b may be covered by another insulating member (not shown) different from the sealing body 30. The semiconductor device 20 may not include the sealing body 30.

What is claimed is:

1. A semiconductor device comprising:
a semiconductor element having a first main electrode and a signal pad on one surface, and having a second main electrode on a back surface opposite to the one surface in a thickness direction;
a first wiring member electrically connected to the first main electrode;
a second wiring member electrically connected to the second main electrode, the semiconductor element being disposed between the first wiring member and the second wiring member in the thickness direction;
a conductive spacer interposed between the semiconductor element and the first wiring member; and
a solder disposed between the second wiring member and the second main electrode, between the first main electrode and the conductive spacer, and between the conductive spacer and the first wiring member, wherein
the conductive spacer has an end surface facing the semiconductor element and a side surface continuous with the end surface,
the side surface has
a recess open in the end surface and located at least adjacent to the pad in a plan view along the thickness direction,
a roughened region in which a roughened oxide film is formed to have a continuously roughened surface, excluding an inner surface of the recess, and
a non-roughened region, in which the roughened oxide film is not formed, on the inner surface of the recess.

2. The semiconductor device according to claim 1, wherein
the end surface of the conductive spacer has a first end surface facing the semiconductor element, and a second end surface facing the first wiring member, and
the recess is opened only in the first end surface.

3. The semiconductor device according to claim 1, wherein
the end surface of the conductive spacer has a first end surface facing the semiconductor element, and a second end surface facing the first wiring member, and
the recess communicates with the first end surface and the second end surface.

4. The semiconductor device according to claim 1, wherein
the recess has a first width at a first position in the thickness direction, and a second width at a second position farther from the semiconductor element than the first position,
the first width is equal to or greater than the second width, and
a width of the recess at an end adjacent to the semiconductor element is greater than a width of the recess an end adjacent to the first wiring member.

5. A semiconductor device comprising:
a semiconductor element including a semiconductor substrate, a first main electrode and a signal pad provided on one surface of the semiconductor substrate, and a second main electrode provided on a back surface opposite to the one surface in a thickness direction;
a first wiring member electrically connected to the first main electrode;
a second wiring member electrically connected to the second main electrode, the semiconductor element being disposed between the first wiring member and the second wiring member in the thickness direction;
a conductive spacer interposed between the semiconductor element and the first wiring member; and
a solder disposed between the second wiring member and the second main electrode, between the first main electrode and the conductive spacer, and between the conductive spacer and the first wiring member, wherein
the first main electrode has a bonding portion bonded with the conductive spacer,
the bonding portion and the pad are arranged in a first direction orthogonal to the thickness direction, and
the semiconductor element includes a dummy wiring extending from an end of the bonding portion of the first main electrode adjacent to the pad and arranged in parallel with the pad in a second direction orthogonal to the thickness direction and the first direction.

6. The semiconductor device according to claim 5, wherein
the semiconductor element includes a plurality of pads arranged in the second direction, and
the dummy wiring extends from the bonding portion of the first main electrode to a space between the pads.

7. The semiconductor device according to claim 5, wherein
the semiconductor element includes a protective film disposed on the one surface, and the protective film has a main opening from which the bonding portion of the first main electrode is exposed to the conductive spacer in a bondable manner,
the first main electrode includes a base layer and an upper layer stacked on the base layer and exposed from the main opening,
the base layer has a peripheral portion positioned outside the main opening in a plan view along the thickness direction,
the protective film has a dummy opening continuous with the main opening and extending from the main opening in the second direction, and
the dummy wiring includes
an overlapping portion overlapping with the dummy opening in a plan view along the thickness direction, which is a peripheral portion of the base layer, and
an extension portion which is continuous with a portion of the base layer exposed from the main opening and is disposed in the dummy opening.

8. The semiconductor device according to claim 7, wherein a thickness of the base layer is smaller at position overlapping with the dummy opening than at position overlapping with the main opening.
